(19) United States
(12) Patent Application Publication
(10) Pub. No.: US 2026/0277358 A1
(43) Pub. Date: Sep. 17, 2026

(54) DIFFERENTIAL TIME CONSTANT-BASED CAPACITIVE SENSOR

(71) Applicant: Semtech Corporation, Camarillo, CA (US)

(72) Inventors: Gert Jan van Sprakelaar, Fremont, CA (US); Julius Minglin Tsai, San Jose, CA (US); Shaoyun Wang, San Jose, CA (US)

(21) Appl. No.: 19/565,873

(22) Filed: Mar. 13, 2026

Related U.S. Application Data
(60) Provisional application No. 63/771,954, filed on Mar. 14, 2025.

(51) Int. Cl. G06F 3/041; G06F 3/044

(52) U.S. Cl. CPC G06F 3/04166; G06F 3/044

(57) ABSTRACT

The present disclosure provides a capacitor sensor system that employs a resistive bridge configuration in conjunction with an amplifier and a sampling circuit to detect changes in capacitive values indicative of touch events. The system comprises a resistive bridge coupled between a drive node and a fixed voltage node, including first and second resistors forming a voltage divider along with a reference capacitor and a touch sensor capacitor. An amplifier is arranged to compare the voltages at two output terminals of the resistive bridge, with the sampled output signal reflecting changes in capacitance value of the touch sensor capacitor. The sampling circuit operates in synchronization with the periodic drive voltage applied to the bridge, enabling precise detection and processing of capacitive events without requiring complex or expensive components. The system's robust and reliable sensing capabilities make it well-suited for a wide range of touch-sensitive applications such as human-device interfaces.

### FIELD OF THE DISCLOSURE

The present disclosure relates generally to capacitive sensing systems and more particularly to capacitor sensor systems utilizing a resistive bridge or constant current source configuration with an amplifier circuit and a synchronized sampling circuitry.

### BACKGROUND

Touch sensors are ubiquitous human machine interface (HMI) devices. Widely used in smart homes, computing, gaming, automotive infotainment, Internet of Things, and mobile devices, these touch sensors all rely on HMI sensors to provide the users with intuitive and reliable user experience.

A number of touch sensor technologies exist, for example, resistive, infrared, ultrasound, inductive, and capacitive. Capacitive sensing is frequently used, and generally either the self-capacitance or mutual capacitance is measured. Self-capacitance can lead to the simplest interface, requiring only a single pin to connect the sensor to the analog front-end.

A common method of sensing self-capacitance is measuring the amount of charge required to charge the sensor. This either is amplified with a charge amplifier (for further signal processing with an analog-to-digital converter) or is directly used as an input capacitance for a capacitance-to-digital converter.
The charge amplifier method leads to a challenging design, requiring a very low noise amplifier and large feedback capacitors, Cf, to avoid signal clipping in case of large parasitic sensor capacitance. It further needs either extremely large feedback resistors, Rf, for biasing or complex switched capacitor feedback.
The capacitance-to-digital converter method requires complex front-end error correction and timing control, resulting in a system on a chip, further complicating the design requirements of the circuits involved.

Furthermore, both methods suffer from increased “noise gain” due to the parasitic capacitance at its inputs, which leads to increased power consumption to maintain low signal-to-noise ratio.

### SUMMARY

The present disclosure provides a capacitor sensor system that employs a resistive bridge configuration in conjunction with an amplifier and a sampling circuit to detect changes in capacitive values indicative of touch events. The system comprises a resistive bridge coupled between a drive node and a fixed voltage node, including first and second resistors forming a voltage divider along with a reference capacitor and a touch sensor capacitor. An amplifier is arranged to compare the voltages at two output terminals of the resistive bridge, with the sampled output signal reflecting changes in capacitance value of the touch sensor capacitor. The sampling circuit operates in synchronization with the periodic drive voltage applied to the bridge, enabling precise detection and processing of capacitive events without requiring complex or expensive components. The system's robust and reliable sensing capabilities make it well-suited for a wide range of touch-sensitive applications such as human-device interfaces.

A differential time constant-based capacitive sensor according to the present disclosure has multiple technical benefits, which may include the following:
Sensor is simple and easy to interface (requires only one pin) and easily configurable to adjust full scale range.
Sensor can be combined with piezoresistive Wheatstone bridge-based sensors, such as force or pressure sensors.
Sensor can also use the same piezoresistive bridge that senses force as a differential capacitive time constant-based sensor.
   These two measurements can provide greater resolution/distinction of touch location and force.
Sensor provides electromagnetic interference rejection (inherent filtering of high frequencies).
Parasitic capacitance (unwanted capacitance from circuitry, packaging, and printed circuit board layout, for example) helps reduce sensor noise, and the bridge output root mean square noise scales as

$$\sqrt{( \frac{kT}{c} )} .$$

Note: For a charge amplifier or capacitance-to-digital converter, the noise scales with Aₙₒᵢₛₑ=[1+(Cₛ+Cₚₐᵣ)]/C_{f}.
Sensor response can be linearized by choosing sampling moment of the differential sensor output.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIG. 1 is a schematic diagram of a capacitive sensor system that is structured in accordance with the present disclosure.

FIG. 2 is a graph depicting a sensor output voltage in response to the drive voltage as a function of time during operation of the embodiment of FIG. 1.

FIG. 3 is a schematic diagram of a capacitive sensor system that includes electronic switches in series with the reference capacitor and the touch sensor capacitor, respectively.

FIG. 4 is a graph of a first output voltage, a second output voltage, a sensor voltage, and a switch control voltage versus time that result from operation of the embodiment of FIG. 3.

FIG. 5 is a graph that depicts a relatively flat area at the peak of sensor voltage that is an amplified difference between the first output voltage and the second output voltage.

FIG. 6 depicts a graph showing peak time versus capacitance of the touch sensor capacitor illustrating how peak characteristics may be controlled through nominal resistance and capacitance configurations.

FIG. 7 is a graph that depicts sampling time options for linearizing the sensor voltage versus touch sensor capacitance.

FIG. 8 is a schematic of an embodiment of the capacitor sensor system that replaces the resistive bridge with a current sourced bridge.

FIG. 9 is a graph illustrating how the sensor voltage scales with a ratio of the reference capacitor to the touch sensor capacitor, with an additional parasitic capacitor in parallel with the touch sensor capacitor.

FIG. 10 is a schematic of an embodiment of the capacitor sensor system having a first damping resistor coupled between the reference capacitor and a first output terminal and a second damping resistor coupled between the touch sensor capacitor and a second output terminal.

FIG. 11 depicts a schematic of an embodiment of the capacitor sensor system where piezoresistive resistors in a resistive bridge, combined with a touch sensor capacitor, provide information on both touch force and capacitance, respectively.

FIG. 12 is a diagram showing how the disclosed capacitor sensor system may interact with user elements such as wireless communication devices.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

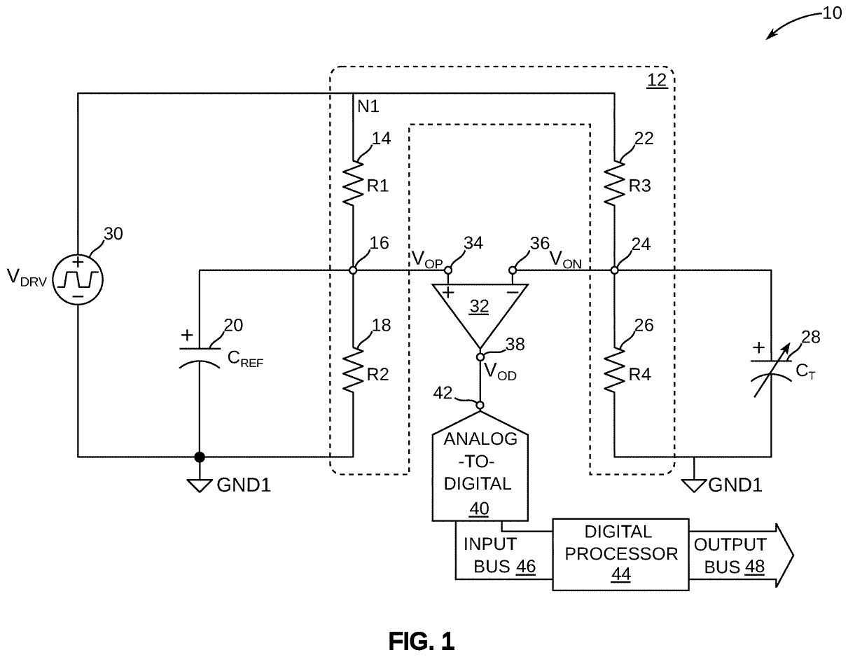

FIG. 1 is a schematic diagram of a capacitive sensor system 10 that is structured in accordance with the present disclosure. The capacitive sensor system 10 includes a resistive bridge 12 that has a first resistor 14, labeled R1, that is coupled between a drive node N1 and a first output terminal 16. A second resistor 18, labeled R2, is coupled between the first output terminal 16 and a fixed voltage node GND1. The fixed voltage node GND1 is typically ground. A reference capacitor 20, labeled C_{REF}, is coupled between the first output terminal 16 and the fixed voltage node GND1. As such, the reference capacitor 20 is coupled in parallel with the second resistor 18. A third resistor 22, labeled R3, is coupled between the drive node N1 and a second output terminal 24. A fourth resistor 26, labeled R4, is coupled between the second output terminal 24 and the fixed voltage node GND1. A touch sensor capacitor 28, labeled C_{T}, is coupled between the second output terminal 24 and the fixed voltage node GND1. As such, the touch sensor capacitor 28 is coupled in parallel with the fourth resistor 26. The touch sensor capacitor 28 has variable capacitance that is typically changed as a function of a user's finger position in on a touch sensor associated with the touch sensor capacitor 28. The variable nature of the capacitance of the touch sensor capacitor 28 is depicted by an arrow drawn through the symbol of the touch sensor capacitor 28. It is important to note that the touch sensor capacitor 28 may be external to the capacitor sensor system 10 because the touch sensor capacitor 28 may be supplied by a customer in some embodiments.

A bridge drive source 30 having a drive voltage V_{DRV} output is coupled between the drive node N1 and the fixed voltage node GND1. In some embodiments, the bridge drive source 30 is configured to output the drive voltage V_{DRV} in voltage pulses at a periodic rate, and in other embodiments, the bridge drive source 30 is configured to output a drive voltage V_{DRV} as a direct current steady-state voltage.

An amplifier 32 has a positive input terminal 34 coupled to the first output terminal 16 to receive a first output voltage V_{OP} that is equal to instantaneous voltage across the reference capacitor 20. The amplifier 32 has a negative input terminal 36 that is coupled to the second output terminal 24 to receive a second output voltage V_{ON} that is equal to instantaneous voltage across the touch sensor capacitor 28. The amplifier 32 has an amplifier output terminal 38 at which a sensor voltage V_{OD} is output. The sensor voltage V_{OD} is equal to the amplified difference between the first output voltage V_{OP} at the first output terminal 16 and the second output voltage V_{ON} at the second output terminal 24. A sampling rate of the sensor voltage V_{OD} is synchronized with the periodic rate of the drive voltage V_{DRV} voltage pulses. In some embodiments, the sampling rate is between 10 Hz and 100 Hz. In other embodiments, the sampling rate is between 100 Hz and 1000 Hz.

In some embodiments, an analog-to-digital converter 40 has a converter input 42 coupled to the amplifier output terminal 38. A digital processor 44 is configured to receive a digital conversion of the sensor voltage V_{OD} over an input bus 46. In some embodiments, the input bus 46 may be a serial bus, and in other embodiments the input bus may be a parallel bus. The digital processor 44 is configured to process the digital conversion of the sensor voltage V_{OD} and sends a resulting output over an output bus 48 that may be coupled to external circuitry such as additional processing circuitry (not shown).

The basic measurement concept is based on the resistor-capacitor-based or constant current time constant τ, in which the time to charge up a capacitance with either a fixed value resistor or constant current varies with capacitance. When used in a resistive bridge configuration, the two sides of the bridge have individual τ values, depending on the capacitive loads on each side. Similar reasoning follows if two constant current sources are used to charge up a reference and sensor capacitor.

In case of a resistive bridge, one can drive the bridge with a constant voltage and connect the sensor capacitors to the bridge at a well-defined switch time (“switch based”), or have the sensor capacitors permanently connected, but turn on the bridge a specific time (“bridge drive-based”). In both cases the differential output of the bridge is measured, and the differential signal provides a measure of the capacitances connected to the bridge. Choosing the sampling moment of the differential output response can further provide advantages of linearizing and/or adjusting signal levels to allow simpler analog front-end (AFE) designs, such as a standard instrumentation amplifier followed by a sample-and-hold or analog-to-digital converter.

In case constant current sources are used, the two (identical) current sources are used to charge up a reference capacitor and the sensor capacitor. The differential signal provides a measure of the capacitances connected to the current sources.

### Resistive Bridge Drive-Based

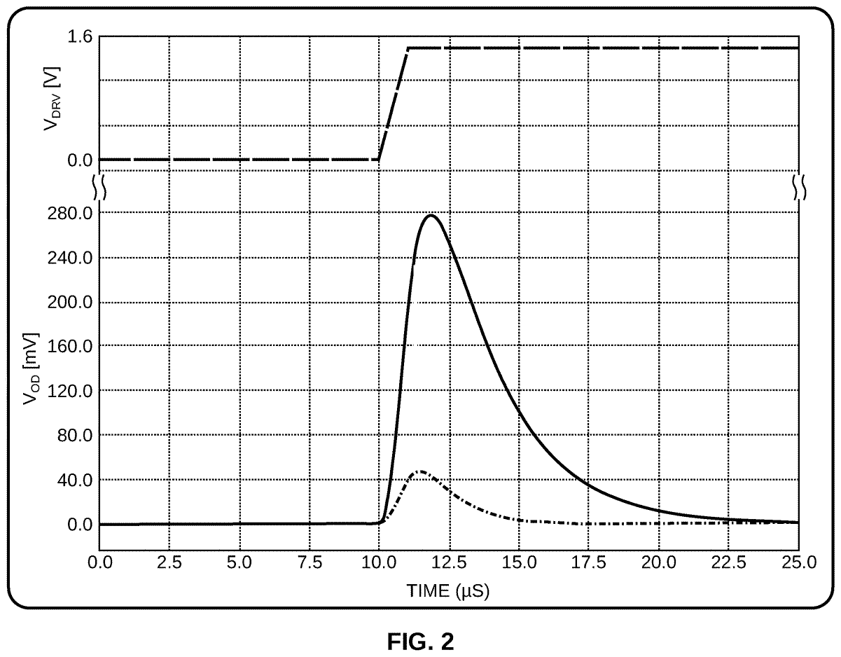

FIG. 2 is a graph depicting the sensor output voltage V_{OD} in response to the drive voltage V_{DRV} as a function of time. In FIG. 2, the drive voltage V_{DRV} is turned on at time=10 μs, and the sensor output voltage V_{OD} is plotted for two example cases, one with a small touch capacitor having a capacitance of 1 picofarad (pF) shown in dot-dash line and one with a large touch capacitor having a capacitance of 10 pF shown in solid line.

### The Switch-Based Resistive Bridge

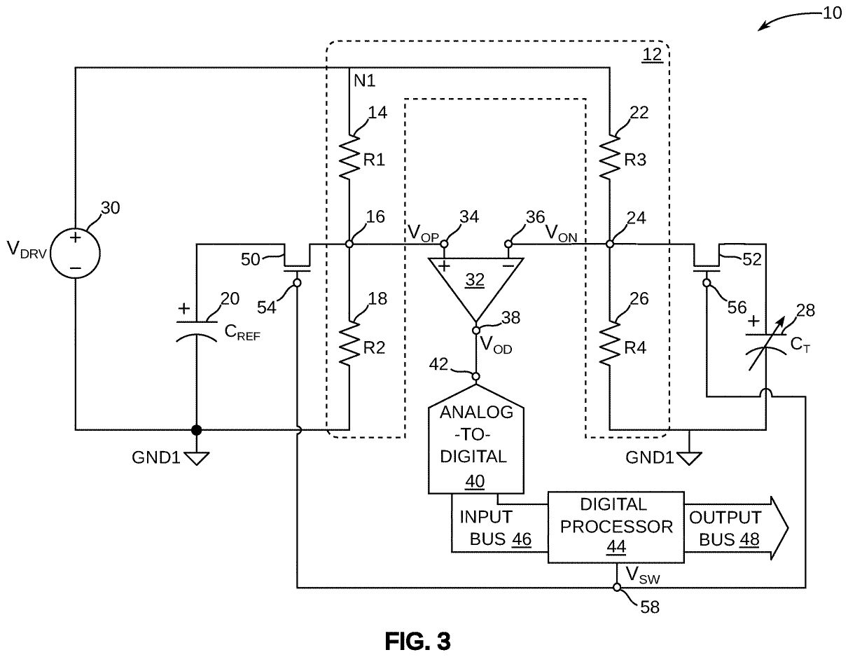

FIG. 3 is a schematic diagram of a capacitive sensor system 10 that includes a first electronic switch 50 coupled in series with the reference capacitor 20 and a second electronic switch 52 coupled in series with the touch sensor capacitor 28, respectively. In exemplary embodiments, the first electronic switch 50 and the second electronic switch 52 are transistors. In the exemplary embodiment depicted in FIG. 3, the first electronic switch 50 and the second electronic switch 52 are field-effect transistors. A first control terminal 54 of the first electronic switch 50 and a second control terminal 56 of the second electronic switch 52 are coupled to a switch control terminal 58 of the digital processor 44. The digital processor 44 is configured to switch the first electronic switch 50 and the second electronic switch 52 between conductive states (i.e., on state) and non-conductive states (i.e., off state) at predetermined times.

During operation of the embodiment of FIG. 3, the resistive bridge 12 is driven with the drive voltage V_{DRV} at a constant voltage. At a predetermined switch time, the reference capacitor 20 and the touch sensor capacitor 28 are electrically coupled to the resistive bridge 12 by way of turning the first electronic switch 50 and the second electronic switch 52 to conductive states by way of a switch control signal V_{SW} that is generated by the digital processor 44.

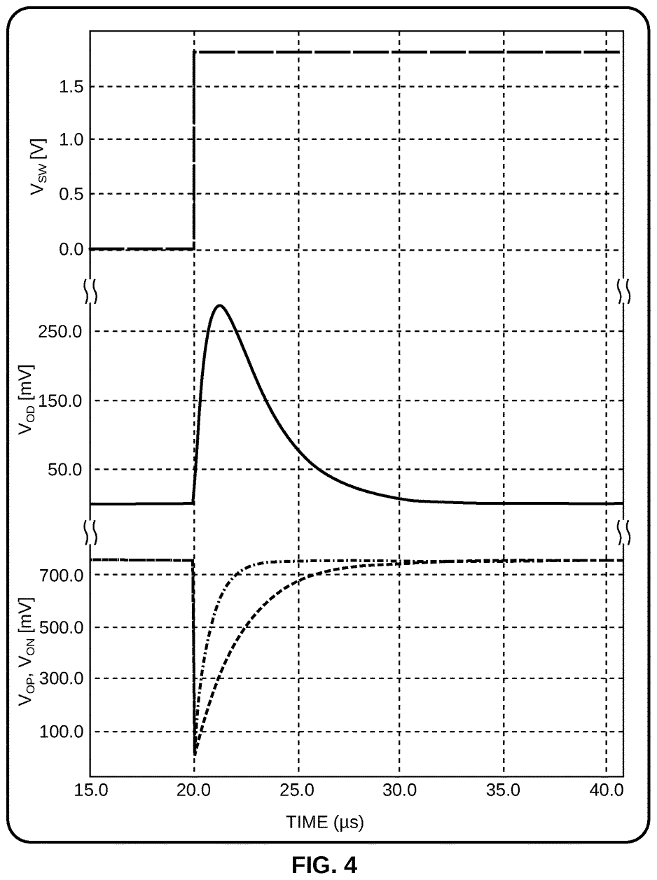

FIG. 4 is a graph of the first output voltage V_{OP}, the second output voltage V_{ON}, the sensor voltage V_{OD}, and the switch control voltage V_{SW} versus time.

In this exemplary case, at t=20 μs the switches connect both the cref and ct. The sensor voltage V_{OD} that is equal to an amplified difference between the first output voltage V_{OP} and the second output voltage V_{ON} is shown in FIG. 4 relative to the switch control voltage V_{SW} and the first output voltage V_{OP} and the second output voltage V_{ON}.

The differential output response that is the sensor voltage V_{OD} versus time may be designed either to maximize the sensor voltage V_{OD} or to linearize the response to the sensor voltage V_{OD} by sampling the sensor voltage V_{OD} at a chosen point in time. For example, sampling after the peak of the sensor voltage V_{OD} provides a more linear response and easier timing control for the AFE.

The response vs. time for a typical case with the touch sensor capacitor 28 being C_{T}=2 pF and the first resistor 14, the second resistor 18, the third resistor 22, and the fourth resistor 26 each having a resistance of 300 kΩ gives the following response for the individual outputs V_{OP}, V_{ON}, and the sensor voltage V_{OD}.

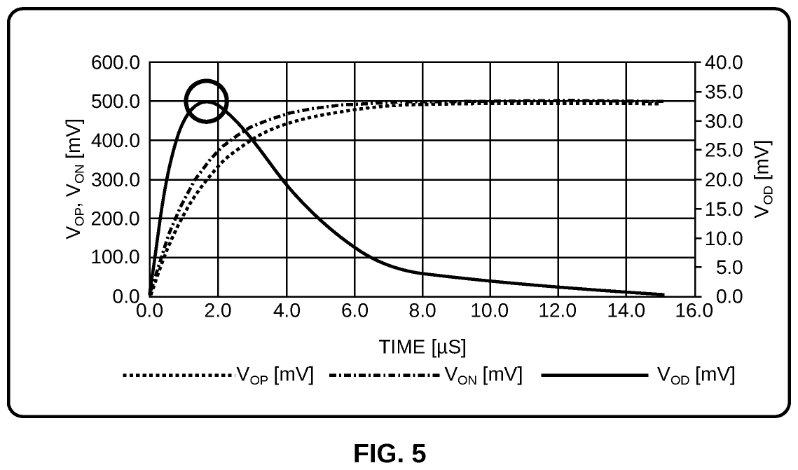

The peak voltage for the sensor voltage V_{OD} and fixed time sample voltage versus C_{T} response is plotted in FIG. 5. To achieve the maximum signal, it is ideal to sample at the peak of the signal. This approach benefits from the fact that the peak area depicted inside a circle in FIG. 5 remains relatively insensitive to timing errors and thus maintains a “flat” response. The time at which this peak occurs can be determined using the equation:

$${t}_{peak} = {( \frac{1}{{τ}_{1}} - \frac{1}{{τ}_{2}} )}^{- 1} \times 1 n ( \frac{{τ}_{2}}{{τ}_{1}} )$$

Here, τ₁ represents the time constant for the resistance R_{BR} and capacitor C_{REF}, while τ₂ is the time constant for the same bridge resistance R_{BR} in conjunction with a different capacitor C_{T}. By applying this equation, a peak sampling point for the sensor voltage V_{OD} can be determined.

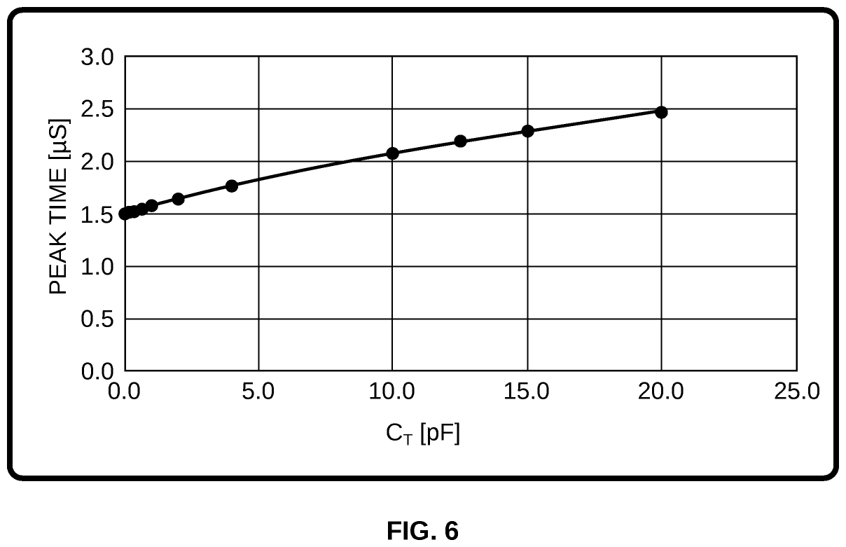

FIG. 6 depicts a graph showing peak time versus capacitance of the touch sensor capacitor 28, where each of the first resistor 14, second resistor 18, third resistor 22, and fourth resistor 26 has a nominal resistance of 400 kΩ. A larger nominal resistance or capacitance for the touch sensor capacitor 28 results in a later peak time and typically a wider peak. Conversely, a smaller nominal resistance or capacitance yields an earlier peak time and generally a narrower peak. Therefore, desired peak characteristics, whether aiming for a later or earlier peak time and a wider or narrower peak, may be achieved by selecting the appropriate nominal resistance for each of the resistors 14, 18, 22, and 26 and/or choosing a suitable nominal capacitance value for the touch sensor capacitor 28.

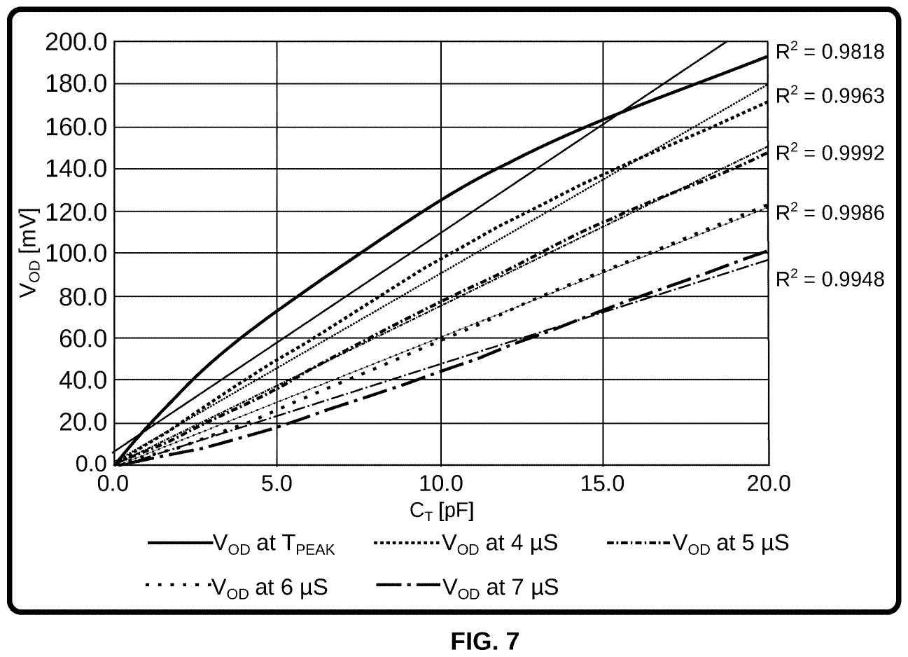

FIG. 7 is a graph that depicts sampling time options for linearizing the sensor voltage V_{OD} versus touch sensor capacitance C_{T}. To effectively linearize the signal, optimizing the sampling time by minimizing the error associated with the linear curve fit and thereby maximizing the R² value is desirable in some applications. The graph depicted in FIG. 7 illustrates the relationship between peak time and sample time versus the capacitance of touch sensor capacitor 28 that is labeled C_{T}, alongside several options for sampling times ranging from 4 to 7 microseconds. It is evident that as the sampling time varies, so does the quality of the linear fit. In this scenario, an R² value reaches its optimum at a sampling time of 5 microseconds. However, it is important to note that selecting this optimal sampling time results in a slight reduction in the sensor voltage V_{OD}.

### Constant Current Differential Output

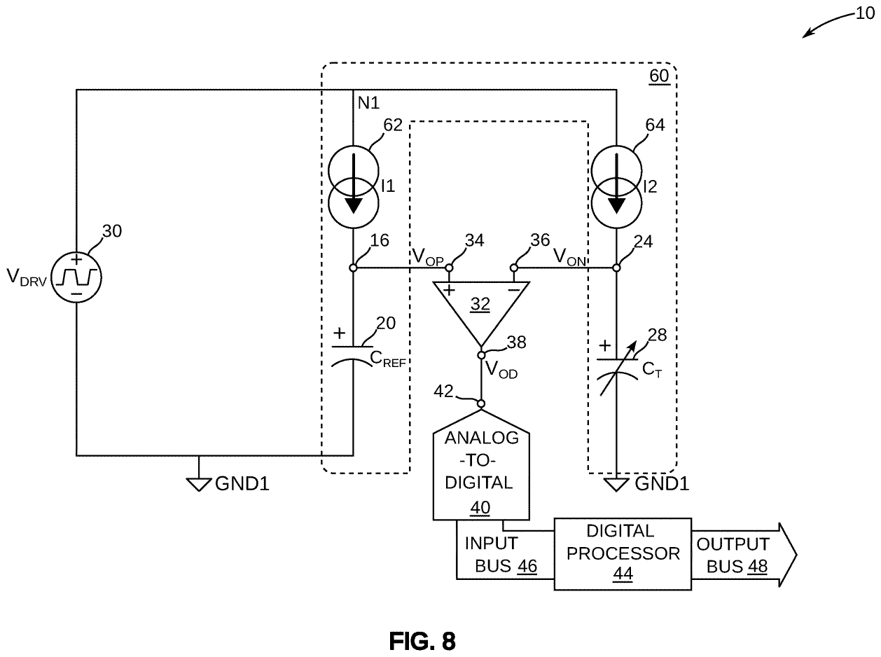

FIG. 8 is a schematic of another embodiment of the capacitor sensor system 10. In this embodiment, a current sourced bridge 60 replaces the resistive bridge 12 depicted in FIG. 1 and FIG. 3. The current sourced bridge 60 has a first constant current source 62, labeled I1, and a second constant current source 64, labeled I2. The first constant current source 62 is coupled in series with the reference capacitor 20 between the supply node N1 and the fixed voltage node GND1. The second constant current source 64 is coupled in series with the touch sensor capacitor 28. In some embodiments, the first constant current source 62 and the second constant current source 64 are practically identical in that they source charging currents that are substantially equal in magnitude for the reference capacitor 20 and the touch sensor capacitor 28, respectively. In other embodiments, the first constant current source 62 and the second constant current source 64 are scaled differently to extend the full-scale range by generating charging currents that have different magnitudes. Additionally, the reference capacitor 20 may have its capacitance trimmed to adjust the full-scale range.

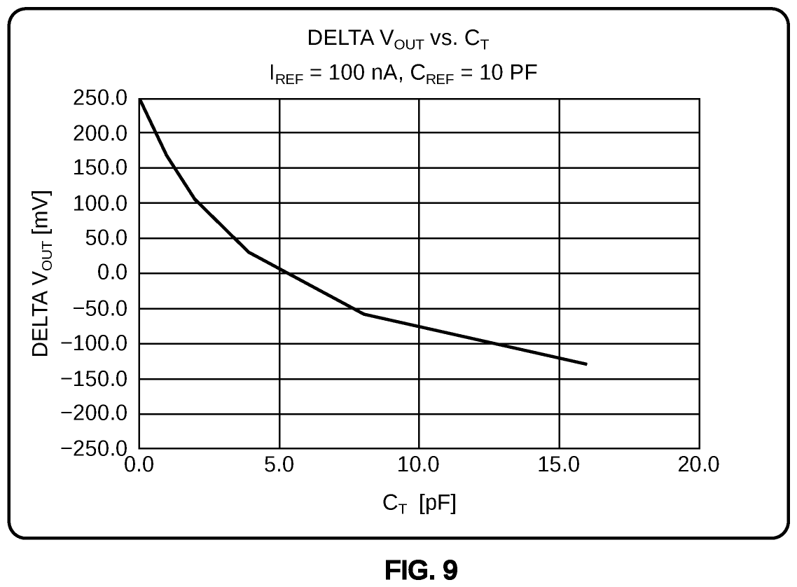

FIG. 9 is a graph illustrating how the sensor voltage scales with a ratio of the reference capacitor to the touch sensor capacitor, with an additional parasitic capacitor in parallel with the touch sensor capacitor. In some embodiments, the additional parasitic capacitor has a capacitance of 5 picofarads. As shown in the graph of FIG. 9, the differential output that is the sensor voltage V_{OD} scales with C_{T}/[C_{T}+C_{REF}]. In the embodiments of this disclosure, the first output voltage V_{OP} and the second output voltage V_{ON} of the resistive bridge 12 or constant current charged capacitors C_{REF} and C_{T} may be amplified with the amplifier 32 and digitized with the analog-to-digital converter 40 for further digital signal processing by way of the digital processor 44 or other processing circuitry known to those skilled in the art.

In summary, the bridge resistors are to set the τ=RC time constant, the small R for fast response at the expense of power and the large R for low power, but slow response. The resistors set the common mode voltage for the AFE. The touch sensing provided by the piezoresistive embodiment of the resistor bridge 12 is used in combination with differential capacitive time constant sensing to provide substantially greater resolution and accuracy of touch location and force exerted by a user's touch relative to either differential capacitive time constant sensing or piezoresistive touch sensing alone. The amplifier 32, analog-to-digital converter 40, and digital processor 44 may be used for both sensing measurements by sampling the differential capacitive time constant signal and the piezoresistive touch signal at different times at substantially close intervals.

The reference capacitor C_{REF} for single-sided measurement provides a reference τ, and reference capacitor C_{REF} can become the second capacitor for a differential capacitance measurement such as for slider button applications.

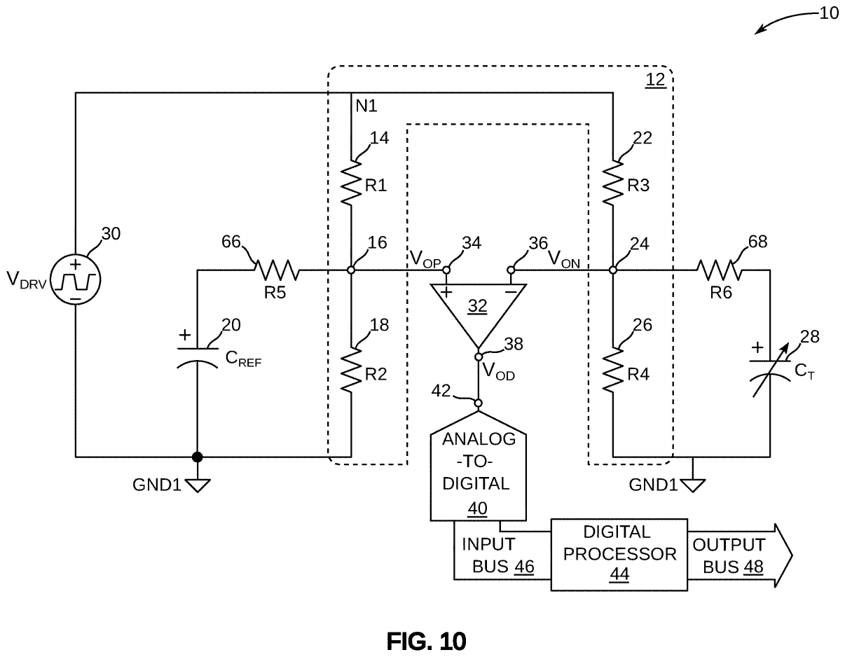

As depicted in FIG. 10, a first damping resistor 66, labeled R5, is coupled between the reference capacitor 20 and the first output terminal 16, and a second damping resistor 68, labeled R6, is coupled between the touch sensor capacitor 28 and the second output terminal 24. The first damping resistor 66 and the second damping resistor 68 are configured to adjust the signal level at the first output terminal 16 and the second output terminal 24 to avoid overdriving the amplifier 32 and to allow for simpler AFE design. The first damping resistor 66 and the second damping resistor 68 also provide electrostatic discharge protection for the amplifier 32.

In the bridge drive voltage V_{DRV} case, the stepped voltage initiates the charging of the capacitors; and in the switched case, the switched control signal V_{SW} determines the moment the capacitors are connected and start the charging up.

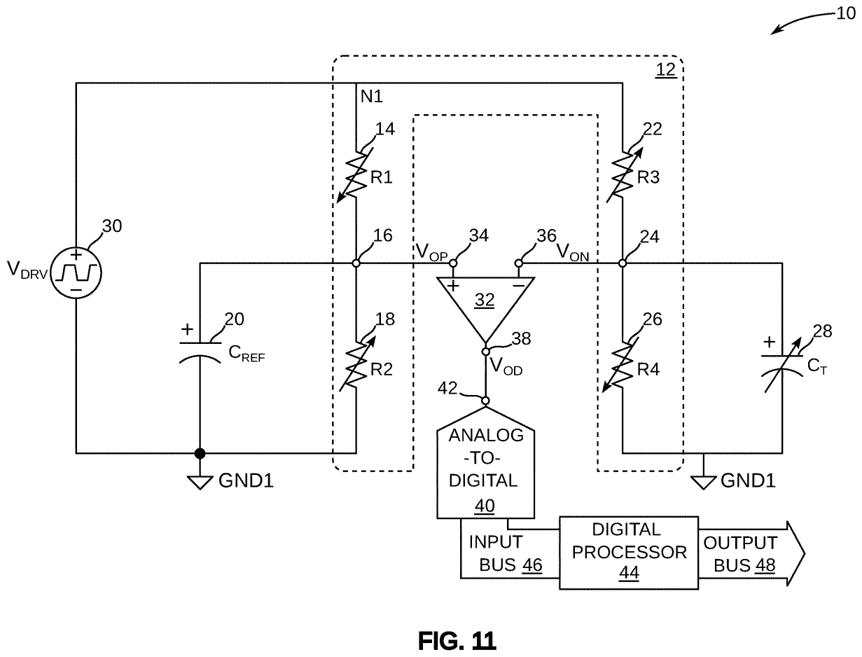

FIG. 11 depicts a schematic of an embodiment of the capacitor sensor system where piezoresistive resistors in a resistive bridge, combined with a touch sensor capacitor, provide information on both touch force and capacitance, respectively. This embodiment is desirable for applications in which enhanced user functions and/or increased accuracy in discerning user input position are required.

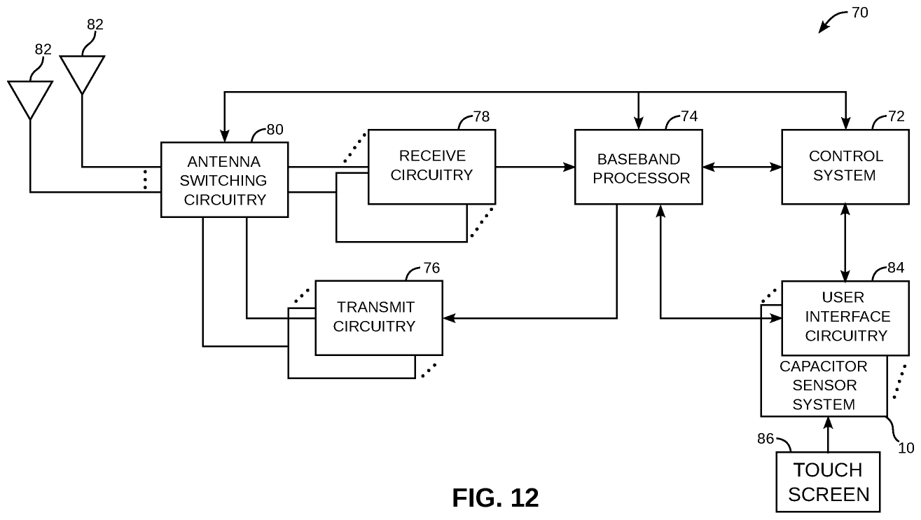

With reference to FIG. 12, the concepts described above may be implemented in various types of wireless communication devices or user elements 70, such as mobile terminals, smart watches, tablets, computers, navigation devices, access points, and the like that support wireless communications, such as cellular, wireless local area network (WLAN), Bluetooth, and near-field communications. The user elements 70 will generally include a control system 72, a baseband processor 74, transmit circuitry 76, receive circuitry 78, antenna switching circuitry 80, multiple antennas 82, and user interface circuitry 84. The user interface circuitry 84 includes the capacitive sensor system 10 that may be configured to receive user input by way of a touch screen 86.

The receive circuitry 78 receives radio frequency signals via the antennas 82 and through the antenna switching circuitry 80 from one or more basestations. A low-noise amplifier and a filter (not shown) cooperate to amplify and remove broadband interference from the received signal for processing. Downconversion and digitization circuitry (not shown) then downconvert the filtered, received signal to an intermediate or baseband frequency signal, which is then digitized into one or more digital streams.

The baseband processor 74 processes the digitized received signal to extract the information or data bits conveyed in the received signal. This processing typically comprises demodulation, decoding, and error correction operations. The baseband processor 74 is generally implemented in one or more digital signal processors and application-specific integrated circuits.

For transmission, the baseband processor 74 receives digitized data, which may represent voice, data, or control information, from the control system 72, which it encodes for transmission. The encoded data are output to the transmit circuitry 76, where they are used by a modulator (not shown) to modulate a carrier signal that is at a desired transmit frequency or frequencies. A power amplifier (not shown) amplifies the modulated carrier signal to a level appropriate for transmission and delivers the modulated carrier signal to the antennas 82 through the antenna switching circuitry 80. The antennas 82 and the replicated transmit circuitry 76 and receive circuitry 78 may provide spatial diversity. Modulation and processing details will be understood by those skilled in the art.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A capacitor sensor system comprising:
a resistive bridge coupled between a drive node and a fixed voltage node, the resistive bridge including:
a first resistor coupled between the drive node and a first output terminal,
a second resistor coupled in series with a reference capacitor between the first output terminal and the fixed voltage node,
a third resistor coupled between the drive node and a second output terminal, and
a fourth resistor coupled in series with a touch sensor capacitor between the second output terminal and the fixed voltage node;
an amplifier having a positive input terminal coupled to the first output terminal, a negative input terminal coupled to the second output terminal, and an amplifier output terminal; and
a sampling circuit synchronized with a periodic rate of a drive voltage applied to the resistive bridge for sampling a sensor voltage at the amplifier output terminal.

2. The capacitor sensor system of claim 1 further comprising electronic switches coupled in series with the reference capacitor and the touch sensor capacitor, the electronic switches configured to switch between conductive states and non-conductive states under control of a processor.

3. The capacitor sensor system of claim 2 wherein the electronic switches are field-effect transistors.

4. The capacitor sensor system of claim 1 further comprising damping resistors coupled between the reference capacitor and the first output terminal, and between the touch sensor capacitor and the second output terminal.

5. The capacitor sensor system of claim 1 wherein the drive voltage is applied as voltage pulses synchronized with a sampling rate of the sampling circuit.

6. The capacitor sensor system of claim 1 further comprising an analog-to-digital converter coupled to the amplifier output terminal for digitizing the sensor voltage.

7. The capacitor sensor system of claim 6 further comprising a digital processor configured to process the digitized sensor voltage and generate an output signal based thereon.

8. The capacitor sensor system of claim 1 wherein the first resistor, the second, resistor, the third resistor, and the fourth resistor each have a resistance in the range of 300 kΩ to 400 kΩ.

9. The capacitor sensor system of claim 1 further comprising constant current sources replacing the resistive bridge for charging the reference capacitor and touch sensor capacitor.

10. The capacitor sensor system of claim 1 wherein the reference capacitor and the touch sensor capacitor each have a capacitance between 1 picofarad (pF) and 100 pf.

11. A method of using a capacitor sensor system, said method comprising:
applying a periodic drive voltage to a drive node of a resistive bridge;
sensing a first output voltage at a first output terminal and a second output voltage at a second output terminal of the resistive bridge, where the first output voltage is across a reference capacitor and the second output voltage is across a touch sensor capacitor, the touch sensor capacitor having variable capacitance based on an external condition;
amplifying the difference between the first and second output voltages to generate a sensor voltage; and
sampling the sensor voltage at predetermined points synchronized with the periodic drive voltage.

12. The method of claim 11 further comprising switching electronic switches coupled in series with the reference capacitor and the touch sensor capacitor to connect or disconnect the capacitors from the resistive bridge at predefined times.

13. The method of claim 11 wherein sampling the sensor voltage occurs after a peak of the sensor voltage has been reached.

14. The method of claim 11 further comprising adjusting the sampling time to linearize the relationship between the sampled sensor voltage and capacitance of the touch sensor capacitor.

15. The method of claim 11 further comprising processing the sampled sensor voltage with an analog-to-digital converter and a digital processor.

16. The method of claim 11 wherein the resistive bridge is piezoresistive and configured to sense the force of a user's touch.

17. The method of claim 16 further comprising sampling a differential capacitive time constant signal and a piezoresistive touch signal at different times at substantially close intervals.

18. A wireless device comprising:
control circuitry;
communication circuitry configured to communicate wirelessly with external devices;
user interface circuitry including the capacitor sensor system of claim 1 for receiving user input based on capacitance changes in a touch sensor capacitor.

19. The wireless device of claim 18 further comprising signal processing circuitry configured to convert a sampled sensor voltage into user commands.

20. The wireless device of claim 18 wherein the communication circuitry is configured for cellular, WLAN, Bluetooth, or near-field communications.

21. The wireless device of claim 18 further comprising a display integrated with the user interface circuitry for providing visual feedback based on sensed capacitance changes.

22. The wireless device of claim 18 configured as a smart watch or a mobile terminal incorporating the capacitor sensor system in a touch screen input mechanism of the smart watch or the mobile terminal.

23. A touch sensor system comprising:
a resistive bridge coupled between a drive node and a fixed voltage node, the resistive bridge including:
a first piezoresistive resistor coupled between the drive node and a first output terminal,
a second piezoresistive resistor coupled in series with a reference capacitor between the first output terminal and the fixed voltage node,
a third piezoresistive resistor coupled between the drive node and a second output terminal, and
a fourth piezoresistive resistor coupled in series with a touch sensor capacitor between the second output terminal and the fixed voltage node;
an amplifier having a positive input terminal coupled to the first output terminal, a negative input terminal coupled to the second output terminal, and an amplifier output terminal; and
a sampling circuit synchronized with a periodic rate of a drive voltage applied to the resistive bridge for sampling a sensor voltage at the amplifier output terminal.

24. The touch sensor system of claim 23 further comprising an analog-to-digital converter coupled to the amplifier output terminal for digitizing the sensor voltage.

25. The touch sensor system of claim 23 further comprising a digital processor configured to process the digitized sensor voltages and generate output signals based thereon.

26. The touch sensor system of claim 25 wherein the digital processor is configured to sample a differential capacitive time constant signal and a piezoresistive touch signal at different times at substantially close intervals to generate the output signals.
